(19) United States
(12) Patent Application Publication
(10) Pub. No.: US 2026/0140198 A1
(43) Pub. Date: May 21, 2026

(54) CIRCUIT ARRANGEMENT FOR MONITORING A RECHARGEABLE BATTERY CELL

(71) Applicant: Schaeffler Technologies AG & Co., KG, Herzogenaurach (DE)

(72) Inventor: Christian Reichinger, Neutraubling (DE)

(73) Assignee: Schaeffler Technologies AG & Co. KG, Herzogenaurach (DE)

(21) Appl. No.: 19/103,059

(22) PCT Filed: Aug. 2, 2023
(86) PCT No.: PCT/EP2023/071412

§ 371 Date: Jan. 19, 2026

(30) Foreign Application Priority Data
Aug. 17, 2022 (DE) 10 2022 208 521.3

(51) Int. Cl. G01R 31/396; B60L 58/12; G01R 31/3835; H01M 10/48

(52) U.S. Cl. CPC G01R 31/396; G01R 31/3835; H01M 10/48; B60L 58/12; H01M 2220/20

(57) ABSTRACT

A circuit arrangement has a main monitoring channel with a first analog-to-digital converter (ADC), a redundant monitoring channel with a second ADC, and a comparison unit. The first ADC carries out an analog-to-digital conversion of a signal provided at its input, which is representative of a cell voltage of the rechargeable battery cell, in order to obtain a first digital cell voltage signal. The second ADC carries out an analog-to-digital conversion of a differential signal which is representative of a difference between a reference voltage or a supply voltage of the second ADC and the signal, in order thus to obtain a second digital level-shifted cell voltage signal. Each ADC is designed to carry out the analog-to-digital conversion of the signal or the differential signal depending on a reference voltage, wherein the reference voltage of the first ADC is equal to the reference voltage of the second ADC.

### CROSS-REFERENCE TO RELATED APPLICATIONS

This application claims priority to PCT Application PCT/EP2023/071412, filed Aug. 2, 2023, which claims priority to German Patent Application No. DE 10 2022 208 521.3, filed Aug. 17, 2022. The disclosures of the above applications are incorporated herein by reference.

### FIELD OF THE INVENTION

The invention relates to a circuit arrangement for monitoring a rechargeable battery cell. The rechargeable battery cell is arranged in a rechargeable battery, such as a traction rechargeable battery of an electric vehicle. The invention furthermore relates to a rechargeable battery system and to a motor vehicle.

### BACKGROUND OF THE INVENTION

With electrification of the powertrain, ever-increasing accuracy requirements are being placed on battery monitoring, in order to improve the range and operational safety of electric vehicles, such as hybrid vehicles (HEV), plug-in hybrid vehicles (PHEV) and fully electric vehicles (BEV). An important point here is the measurement accuracy for cell voltage monitoring. With a high Automotive Safety Integrity Level (ASIL) of class C or D, it is required that the cell voltage be available as a measured value with high accuracy, even in the event of undetected faults. With higher cell voltage measurement accuracy, the traction battery can be operated closer to the cell voltage limits without risk, increasing the achievable range with the same battery capacity. In recent years, the performance of the semiconductor devices used for carrying out battery monitoring has already improved significantly. However, due to the high safety requirements, the measuring circuits, for example the analog-to-digital converters for converting the recorded voltage sensor signals, must be partially redundant, which leads to high costs.

### SUMMARY OF THE INVENTION

The invention is based on the object of providing a circuit arrangement for monitoring a rechargeable battery cell, which enables an accurate and cost-effective determination of a cell voltage of the rechargeable battery cell.

The object is achieved by the features described.

According to a first aspect, the above-mentioned problem is solved by a circuit arrangement for monitoring a rechargeable battery cell. The circuit arrangement has a main monitoring channel with a first analog-to-digital converter (ADC), a redundant monitoring channel with a second ADC, and a comparison unit. The first ADC is designed to carry out an analog-to-digital conversion of a provided signal which is representative of a cell voltage of the rechargeable battery cell, in order thus to obtain a first digital cell voltage signal. The second ADC is designed to carry out an analog-to-digital conversion of a differential signal which is representative of a difference between a reference voltage used by the two ADCs for analog-to-digital conversion and the signal, in order thus to obtain a second digital level-shifted cell voltage signal. Alternatively, the second ADC is designed to carry out an analog-to-digital conversion of a differential signal which is representative of a difference between a supply voltage of the second ADC and the signal, in order thus to obtain the second digital level-shifted cell voltage signal.

The first ADC and the second ADC are designed to carry out the analog-to-digital conversion of the signal or the differential signal depending on the reference voltage, wherein the reference voltage of the first ADC is equal to the reference voltage of the second ADC.

The comparison unit is designed to determine a comparison value according to a predetermined function depending on the digital first cell voltage signal and the digital level-shifted second cell voltage signal. The comparison unit is further designed to provide the comparison value at an output of the comparison unit and/or to compare the comparison value with a predetermined threshold value and, if the comparison value exceeds a predetermined threshold value, to provide an error signal at an output of the comparison unit.

The error signal and/or the comparison signal are provided, for example, for an evaluation unit or a higher-order computing unit.

The comparison value of the digital first cell voltage signal and the digital level-shifted second cell voltage signal is determined again at predetermined time intervals.

The use of a common reference voltage by the first and second ADC enables space and cost savings in the implementation of the two ADCs. However, due to the common reference voltage of the first and second ADC, a common-mode error of the reference voltage affects the first ADC and the second ADC equally. The circuit arrangement makes it possible to detect this common-mode error through the special comparison and no further safety mechanisms are required. The measurement accuracy are thus significantly improved.

In at least one embodiment according to the first aspect, the circuit arrangement is formed as an integrated circuit. This makes compact and cost-effective implementation possible. Since the comparison of the output signals of the first ADC and the second ADC takes place in the same integrated circuit, it is very easy to avoid runtime differences between the two measurement results, which makes possible a substantially more accurate comparison and thus a substantially more reliable verification of the first ADC.

In at least one embodiment according to the first aspect, the circuit arrangement has a reference voltage source which provides the reference voltage for the first ADC and the second ADC. The use of a common reference voltage source enables a more cost-effective and space-saving manufacture of the circuit arrangement.

In at least one embodiment according to the first aspect, the first ADC and the second ADC each have a first input terminal for receiving a first measurement signal which is representative of a potential at a positive pole of the rechargeable battery cell. Furthermore, the first ADC and the second ADC each have a second input terminal for receiving a second measurement signal which is representative of a potential at a negative pole of the rechargeable battery cell.

The first ADC has a first level converter on the input side, which is designed to form a first cell potential difference between the first measurement signal and the second measurement signal, wherein the first measurement signal represents the minuend and the second measurement signal represents the subtrahend. The first cell potential difference therefore corresponds with the cell voltage of the rechargeable battery cell or corresponds to the cell voltage of the rechargeable battery cell.

The second ADC has a second level converter on the input side, which is designed to form a second cell potential difference between the second measurement signal and the first measurement signal, wherein the second measurement signal represents the minuend and the first measurement signal represents the subtrahend. The second level converter is further designed to provide the differential signal for the second ADC, if the differential signal is representative of a difference between the reference voltage and the signal, by adding the second cell potential difference and the reference voltage, and, if the differential signal is representative of a difference between the supply voltage of the second ADC and the signal, to provide the differential signal for the second ADC by adding the second cell potential difference and the supply voltage of the second ADC.

In an embodiment, the first ADC and the second ADC have the same supply voltage.

In at least one configuration according to the first aspect, the comparison function represents the sum of the digital first cell voltage signal and the digital level-shifted second cell voltage signal minus the reference voltage, if the differential signal is determined depending on the reference voltage. If the differential signal is determined depending on the supply voltage of the second ADC, the comparison function represents the sum of the digital first cell voltage signal and the digital level-shifted second cell voltage signal minus a setpoint of the supply voltage of the second ADC.

In at least one configuration according to the first aspect, the circuit arrangement has a first analog filter connected upstream of the first ADC and/or a second analog filter connected upstream of the second ADC. In an embodiment, the first and second filter are part of the integrated circuit and/or the first filter and the second filter have different frequency responses.

The different frequency responses are such that the difference in the frequency responses caused by pre-processing may be at least partially compensated.

In at least one configuration according to the first aspect, the first ADC and the second ADC differ in their resolution and/or their settling time.

According to a second aspect, the above-mentioned problem is solved by a rechargeable battery system which has a rechargeable battery with at least one rechargeable battery cell. Furthermore, the rechargeable battery system has a circuit arrangement according to the first aspect in each case for all or at least some of the rechargeable battery cells.

According to a third aspect, the above-mentioned problem is solved by a motor vehicle which has a rechargeable battery system according to the second aspect.

Optional configurations of the first aspect may also be present accordingly in the other aspects and may have corresponding effects.

Exemplary embodiments of the invention are explained in more detail below on the basis of the schematic drawings. In the figures, the same reference signs are used for elements with essentially the same function, but these elements do not have to be identical in all details.

The description of the subjects specified here is not limited to the individual special embodiments.

Features of different exemplary embodiments may—as far as technically reasonable—be combined with each other in order to form further exemplary embodiments. For example, variations or modifications described with respect to one of the exemplary embodiments may also be applicable to other exemplary embodiments, unless specified otherwise.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

In the drawings:

FIG. 1 shows an exemplary block diagram for a circuit arrangement for monitoring a rechargeable battery cell,

FIG. 2 shows an exemplary equivalent circuit diagram of a first level converter, and

FIG. 3 shows an exemplary equivalent circuit diagram of a second level converter.

### DETAILED DESCRIPTION OF THE PREFERRED EMBODIMENTS

The following description of the preferred embodiment(s) is merely exemplary in nature and is in no way intended to limit the invention, its application, or uses.

It is pointed out that, if an element is referred to as being “connected” or “coupled” to another element, the element may be connected or coupled directly to the other element or intermediate elements may be present. In contrast, if an element is referred to as being “connected” or “coupled” “directly” to another element, there are no intermediate elements present. Other expressions used to describe the relationship between elements should be interpreted in the same way (e.g. “between” versus “directly between”, “adjacent” versus “directly adjacent”, etc.).

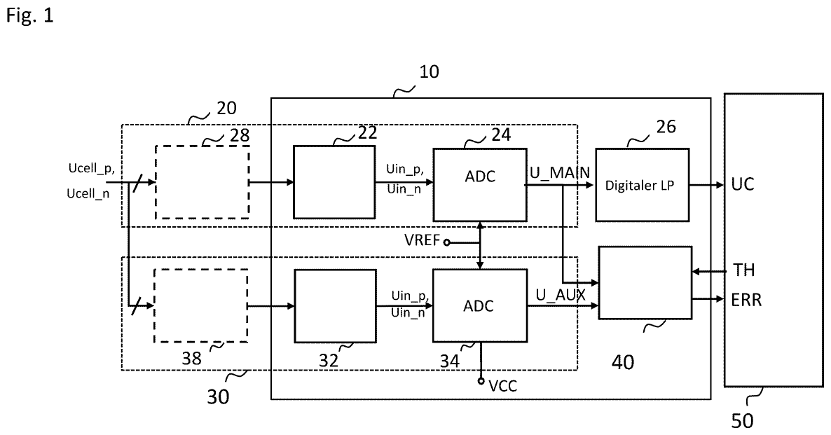

The functions of the circuit arrangement for monitoring a rechargeable battery cell are explained below in relation to FIG. 1, which is a simplified representation of the circuit according to the invention, in which many of the basic components have been omitted for the sake of clarity.

FIG. 1 shows an exemplary block diagram of an exemplary embodiment of a circuit arrangement 10 for monitoring a rechargeable battery cell of a rechargeable battery (rechargeable battery cell and rechargeable battery are not shown in FIG. 1). The rechargeable battery may has a plurality of rechargeable battery cells which are connected in parallel and/or in series. The rechargeable battery is formed, for example, as a traction rechargeable battery for a vehicle.

The rechargeable battery cell is connected to the circuit arrangement 10 and the circuit arrangement receives a first cell potential signal Ucell_p and a second cell potential signal Ucell_c from the rechargeable battery cell on the input side directly or indirectly via a preprocessing unit.

The circuit arrangement 10 has a main monitoring channel 20 with a first analog-to-digital converter, ADC, 24 and a redundant monitoring channel 30 with a second ADC 34. Furthermore, the circuit arrangement 10 has a comparison unit 40.

The circuit arrangement 10 is formed as an integrated circuit in a semiconductor chip. In an embodiment, the semiconductor chip may include several such circuit arrangements 10, and therefore several rechargeable battery cells may be monitored with the semiconductor chip.

The main monitoring channel 20 has, for example, an analog first filter 22 on the input side. The first ADC 24 is connected downstream of the first filter 22. For example, the analog first filter 22 of the main monitoring channel 20 is directly or indirectly connected to the rechargeable battery cell. The analog first filter 22 is used for signal processing of the cell potential signals Ucell_p, Ucell_n received from the rechargeable battery cell.

A digital low pass filter 26, for example, is connected downstream of the first ADC 24. For example, at the output of the digital low pass filter 26, a filtered digital cell voltage signal UC, which represents the cell voltage of the connected rechargeable battery cell, is provided for an evaluation unit 50. The evaluation unit 50 is a control unit assigned to the circuit arrangement or a higher-order computing unit.

The redundant monitoring channel 30 of the circuit arrangement 10 has, for example, an analog second filter 32 on the input side. The second ADC 34 is connected downstream of the second filter 32. The analog second filter 32 of the redundant monitoring channel 30 is connected, for example, directly or indirectly to the rechargeable battery cell. The analog second filter 32 is used for signal processing of the cell potential signals Ucell_p, Ucell_n received from the rechargeable battery cell.

In an optional configuration, a first discrete hardware filter 28 and a second discrete hardware filter 38 are connected upstream of the circuit arrangement, wherein the first discrete hardware filter 28 is connected upstream of the first filter of the main monitoring path 20 and the second discrete hardware filter 38 is connected upstream of the second filter 32 of the redundant monitoring path.

The input of the first ADC 24 has a first input terminal for receiving a first measurement signal Uin_p which is representative of a potential at a positive pole of the rechargeable battery cell, and a second input terminal for receiving a second measurement signal Uin_n which is representative of a potential at a negative pole of the rechargeable battery cell.

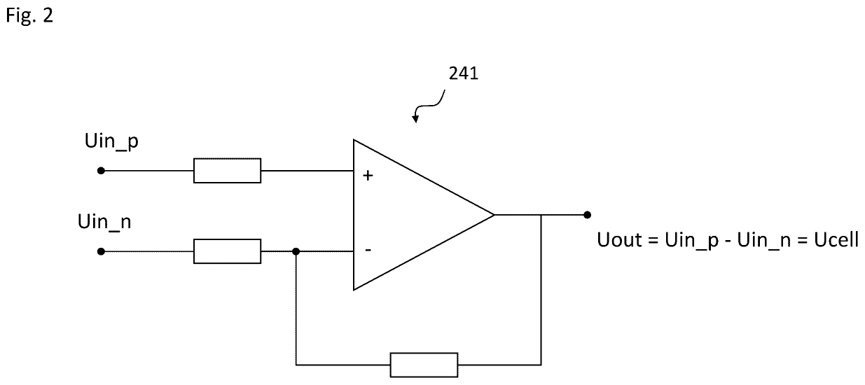

The first ADC 24 includes a first level converter 241. FIG. 2 shows an exemplary equivalent circuit diagram of the first level converter 241 of the first ADC 24.

The first level converter 241 is designed to form a first cell potential difference between the first measurement signal Uin_p and the second measurement signal Uin_n. The first cell potential difference may also be referred to as cell voltage Ucell.

The first ADC 24 (see FIG. 1) furthermore has a converter unit which is designed to carry out the actual analog-to-digital conversion of the cell voltage Ucell and to provide a digital first cell voltage signal U_MAIN at the output of the converter unit.

The input of the second ADC 34 has a first input terminal for receiving the first measurement signal Uin_p which is representative of the potential at the positive pole of the rechargeable battery cell, and a second input terminal for receiving the second measurement signal Uin_n which is representative of the potential at the negative pole of the rechargeable battery cell.

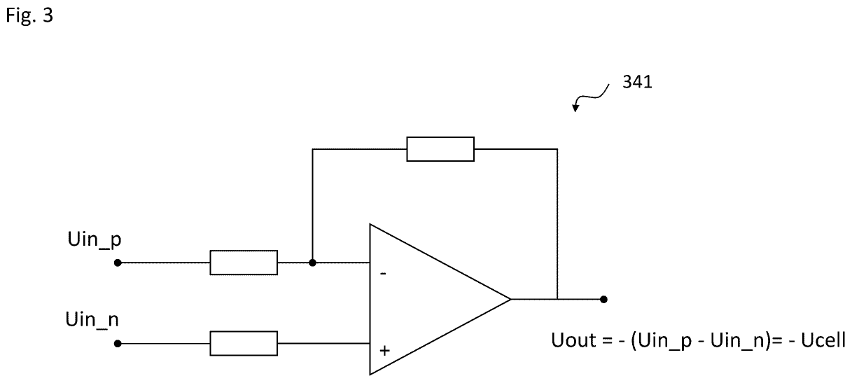

The second ADC 34 includes a second level converter 341. FIG. 3 shows a simplified exemplary equivalent circuit diagram of the second level converter 341 of the second ADC 34.

The second level converter 341 is designed to form a second cell potential difference between the second measurement signal Uin_n and the first measurement signal Uin_p, wherein the second measurement signal represents the minuend and the first measurement signal represents the subtrahend. The second level converter 341 is further designed to provide a differential signal U_{diff} for the second ADC 34 by adding the supply voltage VCC of the second ADC and the second cell potential difference.

Alternatively, the second level converter 341 is designed to provide the differential signal U_{diff} for the second ADC 34 by adding a reference voltage VREF, which the two ADCs use for the analog-to-digital conversion, and the second cell potential difference.

The second ADC 34 (see FIG. 1) includes a converter unit which is designed to carry out the actual analog-to-digital conversion of the differential signal U_{diff} and to provide a digital second cell voltage signal U_AUX at the output of the converter unit.

The converter units of the first ADC 24 and the second ADC 34 may be the same or different. In an embodiment, the second ADC 34 may have a lower resolution and/or a longer settling time, as it is sufficient that the comparison takes place only at certain time intervals. This makes cost-effective implementation possible and the required reliability is still guaranteed.

The first ADC 24 and the second ADC 34 are designed to carry out the analog-to-digital conversion of the cell voltage Ucell or the differential signal U_{diff} depending on a reference voltage VREF which is the same for both ADCs 24, 34. In an embodiment, the first ADC 24 and the second ADC 34 use the same reference voltage source.

The comparison unit 40 of the circuit arrangement (see FIG. 1) is designed to determine a comparison value, in each case, according to a predetermined comparison function depending on the digital first cell voltage signal U_MAIN and the digital level-shifted second cell voltage signal U_AUX, and if the comparison value exceeds a predetermined threshold value TH, to provide an error signal ERR at an output of the comparison unit.

The comparison function includes, if the supply voltage VCC is used for the level shift for the second ADC 34, the sum of the digital first cell voltage signal U_MAIN and the digital level-shifted second cell voltage signal U_AUX minus a setpoint VCC_set of the supply voltage of the second ADC 34.

The digital comparison mechanism in each case thus delivers, as a result, the comparison values

$$U\_delta = U\_MAIN + U\_AUX - VCC \qquad Eq . ( 1 a )$$

If the reference voltage VREF is used for the level shift for the second ADC 34, the comparison function includes the sum of the digital first cell voltage signal U_MAIN and the digital level-shifted second cell voltage signal U_AUX minus the reference voltage VREF.

In this case, the digital comparison mechanism in each case delivers, as a result, the comparison values

$$U\_delta = U\_MAIN + U\_AUX - VREF \qquad Eq . ( 1 b )$$

Furthermore, the comparison unit is designed to provide an error signal at an output of the comparison unit if the comparison value exceeds a predetermined threshold value.

The first ADC 24 and second ADC 34 use the same reference voltage VREF. In the event of the reference voltage VREF deviating upwards by 10% due to an error, the first ADC 24 determines, for the rechargeable battery cell, a cell voltage of

$$U\_MAIN = 1.1 * {U}_{cell} \qquad Eq . ( 2 )$$

and the second ADC 34 determines, when the supply voltage VCC is used for the level shift, a level-shifted cell voltage of

$$U\_AUX = 1.1 * VCC\_act - 1.1 * {U}_{cell} , \qquad Eq . ( 3 a )$$

wherein U_{cell} is the measured cell voltage of the rechargeable battery cell and VCC_act is the real value or actual value of the supply voltage.

When the reference voltage VREF is used for the level shift, the second ADC 34 determines the level-shifted cell voltage

$$U\_AUX = 1.1 * VREF - 1.1 * {U}_{cell} . \qquad Eq . ( 3 b ) .$$

If the supply voltage VCC is used for the level shift at the second ADC 34 and assuming that the setpoint VCC_set and the actual value VCC_act are the same as the supply voltage

$$VCC\_set = VCC\_act = VCC , \qquad Eq . ( 4 ) ,$$

the comparison unit 40 establishes a comparison value of

$$U\_delta = U\_MAIN + U\_AUX - VCC = 0.1 * VCC \qquad Eq . ( 5 a )$$

In the case of a supply voltage of, for example, VCC=5 V, this corresponds to 0.5 V.

When the reference voltage VREF is used for the level shift of the second ADC 34, the comparison value becomes:

$$U\_delta = U\_MAIN + U\_AUX - VREF = 0.1 * VREF . \qquad Eq . ( 5 b )$$

If the comparison value U_delta, for example an absolute value of the comparison value U_delta, exceeds a predetermined threshold value TH, it must be assumed that the reference voltage VREF has an error.

For example, the threshold value TH may be 0 V. However, a threshold value that takes a certain tolerance range into account may be selected for an error decision. In an embodiment, the threshold value TH may also be predetermined depending on a temperature, for example depending on a temperature of the rechargeable battery cells. The threshold value TH is predetermined, for example, by the microcontroller or the higher-order computing unit, which is connected to the comparison unit.

Alternatively, it is possible that the comparison with the threshold value is carried out in the microcontroller or the higher-order computing unit.

The description of the invention is merely exemplary in nature and, thus, variations that do not depart from the gist of the invention are intended to be within the scope of the invention. Such variations are not to be regarded as a departure from the spirit and scope of the invention.

### LIST OF REFERENCE SIGNS

10 circuit arrangement
20 main monitoring channel
22 analog first filter
24 first ADC
241 first level converter
26 digital filter
30 redundant monitoring channel
32 analog second filter
34 second ADC
341 second level converter
40 comparison unit
50 evaluation unit
ERR error signal
UC cell voltage
U_MAIN first cell voltage signal
U_AUX second level-shifted cell voltage signal
TH threshold value
VCC supply voltage
VREF reference voltage

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. A circuit arrangement for monitoring a rechargeable battery cell of a rechargeable battery, the circuit arrangement comprising:
a main monitoring channel further comprising:
a first analog-to-digital converter (ADC), the first ADC carries out an analog-to-digital conversion of a provided signal which is representative of a cell voltage of the rechargeable battery cell, in order to obtain a first digital cell voltage signal;
a redundant monitoring channel having a second ADC, the second ADC carries out an analog-to-digital conversion of a differential signal which is representative of a difference between a reference voltage or a supply voltage of the second ADC and the provided signal, in order to obtain a second digital level-shifted cell voltage signal; and
a comparison unit;
wherein the first ADC and the second ADC carry out the analog-to-digital conversion of the signal or the differential signal depending on the reference voltage and the reference voltage of the first ADC is equal to the reference voltage of the second ADC;
wherein the comparison unit determines, in each case, a comparison value according to a predetermined comparison function depending on the digital first cell voltage signal and the digital level-shifted second cell voltage signal and to provide the comparison value at an output of the comparison unit and/or to compare the comparison value with a predetermined threshold value and, if the comparison value exceeds the predetermined threshold value, to provide an error signal at an output of the comparison unit.

13. The circuit arrangement of claim 12, wherein the circuit arrangement is formed as an integrated circuit.

14. The circuit arrangement of claim 12, the circuit arrangement further comprising a reference voltage source which provides the reference voltage for the first ADC and the second ADC.

15. The circuit arrangement of claim 12, the first ADC further comprising:
a first level converter;
wherein the input of the first ADC has a first input terminal for receiving a first measurement signal which is representative of a potential at a positive pole of the rechargeable battery cell, and a second input terminal for receiving a second measurement signal which is representative of a potential at a negative pole of the rechargeable battery cell;
wherein the first level converter forms a first cell potential difference between the first measurement signal and the second measurement signal, and thus provide the signal for the first ADC.

16. The circuit arrangement of claim 12, the second ADC further comprising:
a second level converter;
wherein an input of the second ADC has a first input terminal for receiving a first measurement signal which is representative of a potential at a positive pole of the rechargeable battery cell, and a second input terminal for receiving a second measurement signal which is representative of a potential at a negative pole of the rechargeable battery cell;
wherein the second level converter forms a second cell potential difference between the second measurement signal and the first measurement signal, such that the second measurement signal forms the minuend and the first measurement signal forms the subtrahend;
wherein the second level converter provides the differential signal for the second ADC by adding the reference voltage or the supply voltage of the second ADC and the second cell potential difference.

17. The circuit arrangement of claim 12, wherein a comparison function of the comparison unit represents the sum of the digital first cell voltage signal and the digital level-shifted second cell voltage signal minus the reference voltage or minus a setpoint of the supply voltage of the second ADC.

18. The circuit arrangement of claim 12, further comprising a first analog filter connected upstream of the first ADC, and/or a second analog filter connected upstream of the second ADC.

19. The circuit arrangement of claim 18, wherein the first filter and the second filter have different frequency responses.

20. The circuit arrangement of claim 12, wherein the first ADC and the second ADC differ in their resolution and/or in settling time.

21. A rechargeable battery system, comprising:
a rechargeable battery, further comprising:
at least one rechargeable battery cell and in each case for all or at least some of the rechargeable battery cells a circuit arrangement of claim 12.

22. A motor vehicle having a rechargeable battery system of claim 21.
